(19) United States
(12) Patent Application Publication
(10) Pub. No.: US 2024/0207977 A1
(43) Pub. Date: Jun. 27, 2024

(54) LASER ANNEALING APPARATUS AND LASER ANNEALING METHOD

(71) Applicant: APS Research Corporation, Hwaseong-si, Gyeonggi-do (KR)

(72) Inventors: Seung Hwan KIM, Hwaseong-si, Gyeonggi-do (KR); Jae Yong KIM, Uiwang-si, Gyeonggi-do (KR); Jin Woo SUNG, Hwaseong-si, Gyeonggi-do (KR); Jong Kab PARK, Hwaseong-si, Gyeonggi-do (KR)

(21) Appl. No.: 17/911,611

(22) PCT Filed: Jul. 5, 2022
(86) PCT No.: PCT/KR2022/009685

§ 371 Date: Jan. 12, 2023

(30) Foreign Application Priority Data
Jul. 6, 2021 (KR) 10-2021-0088421
Jun. 13, 2022 (KR) 10-2022-0071618

(51) Int. Cl. B23K 26/53; B23K 26/067; B23K 26/08; B23K 26/082; B23K 101/40

(52) U.S. Cl. CPC B23K 26/53; B23K 26/0673; B23K 26/082; B23K 26/0869; B23K 2101/40

(57) ABSTRACT

The present inventive concept relates to a laser annealing apparatus and a laser annealing method, which are capable of coping with various thicknesses of an object to be processed and various processes with respect to the object to be processed. The laser annealing apparatus includes: a stage configured to support a target object; a first laser head unit connected to a first laser source unit to irradiate a first laser to the target object; a second laser head unit connected to a second laser source unit to irradiate a second laser having a wavelength longer than that of the first laser to the target object; and a control unit configured to control driving of the first laser head unit and the second laser head unit, wherein the wavelength of the first laser is variable by the control unit.

### TECHNICAL FIELD

The present inventive concept relates to a laser annealing apparatus and a laser annealing method, and more particularly, to a laser annealing apparatus and a laser annealing method, which are capable of coping with various thicknesses of an object to be processed and various processes with respect to the object to be processed.

### BACKGROUND ART

Manufacturing of semiconductor devices requires processes of annealing semiconductor wafer such as silicon (Si) wafers. The annealing may include dopant activation and crystallization due to melting.

For example, in impurity activation, a dopant may be implanted into a semiconductor wafer by ion implantation, and the implanted impurities may be activated by irradiating a laser beam. In addition, in the crystallization due to the melting, the laser beam may be irradiated onto amorphous silicon (a-Si) to be melted and crystallized, thereby forming crystalline silicon single or (e.g., crystal silicon polycrystalline silicon).

According to the related art, there is a limitation in controlling a diffusion depth of the impurities in the laser-based impurity activation, and thus, the impurities are diffused up to an unintentional depth, and as a result, leakage current in the semiconductor device increases, or, recently, it has been difficult to from a shallow junction due to miniaturization in size of the semiconductor device.

In addition, recently, when semiconductor devices are manufactured, a void may occur due to step coverage during a thin film formation process, and thus, development of laser annealing technologies for removing the void in the semiconductor device through the melting process using a laser is being required.
[PATENT DOCUMENT 1] Korean Patent Publication No. 10-2004-0046644

### DISCLOSURE

### Technical Problem

The present inventive concept provides a laser annealing apparatus and a laser annealing method, which are capable of performing a non-melting process and a melting process as well as controlling a annealing depth of a target object.

### Technical Solution

A laser annealing apparatus according to an embodiment of the present inventive concept includes: a stage configured to support a target object; a first laser head unit connected to a first laser source unit to irradiate a first laser to the target object; a second laser head unit connected to a second laser source unit to irradiate a second laser having a wavelength longer than that of the first laser to the target object; and a control unit configured to control driving of the first laser head unit and the second laser head unit, wherein the wavelength of the first laser is variable by the control unit.

The first laser source unit may include: a first wavelength laser light source configured to generate a first wavelength laser having a blue wavelength band; a second wavelength laser light source configured to generate a second wavelength laser having a green wavelength band; and a third wavelength laser light source configured to generate a third wavelength laser having a red wavelength band.

The control unit may selectively drive one or more of the first wavelength laser light source, the second wavelength laser light source, and the third wavelength laser light source to allow the wavelength of the first laser to vary.

The laser annealing apparatus may further include: a head moving unit configured to move the first laser head unit and the second laser head unit; a first optical fiber cable provided between the first laser source unit and the first laser head unit; and a second optical fiber cable provided between the second laser source unit and the second laser head unit.

The control unit may control in a selective driving of any one of the first laser head unit and the second laser head unit or a simultaneous driving of the first laser head unit and the second laser head unit.

A beam size of the first laser may be equal to or greater than that of the second laser in the simultaneous driving of the first laser head unit and the second laser head unit.

The control unit may control scanning of the first laser head unit and the second laser head unit in the simultaneous driving of the first laser head unit and the second laser head unit so that the first laser and the second laser overlap each other, or the first laser is disposed in front of the second laser in a scan direction.

The laser annealing apparatus may further include an irradiation angle adjusting unit configured to adjust each of a laser irradiation angle of the first laser head unit and a laser irradiation angle of the second laser head unit.

The control unit may control scanning of the second laser head unit under different scan conditions for each area by dividing into a plurality of areas.

The laser annealing method according to another embodiment of the present inventive concept may include: a process of selecting at least one laser head unit of a first laser head unit that irradiates a first laser having a variable wavelength and a second laser head unit that irradiates a second laser having a wavelength greater than that of the first laser; and a process of irradiating a laser corresponding to each laser head unit of the first laser and the second laser to a target object from the laser head unit selected from the first laser head unit and the second laser head unit.

The laser annealing method may further include varying the wavelength of the first laser, by selectively driving one or more of a first wavelength laser light source that generates a first wavelength laser having a blue wavelength band, a second wavelength laser light source that generates a second wavelength laser having a green wavelength band and a third wavelength laser light source that generates a third wavelength laser having a red wavelength band.

The laser annealing method may further include setting driving of the first laser head unit and the second laser head unit to selective driving or simultaneous driving, wherein, in the selecting at least one laser head unit, the at least one laser head unit may be selected from the first laser head unit and the second laser head unit according to the set driving of the first laser head unit and the second laser head unit.

In the setting of the selective driving or the simultaneous driving, when activating at least a portion of the target object, the simultaneous driving may be set.

The laser annealing method may further include: generating free carriers by the first laser; and absorbing the second laser to activate impurities in the target object.

The laser annealing method may further include adjusting each of a laser irradiation angle of the first laser head unit and a laser irradiation angle of the second laser head unit.

In the setting of the selective driving or the simultaneous driving, when activating at least a portion of the target object, the selective driving of the first laser head unit may be set.

In the varying the wavelength of the first laser, the wavelength of the first laser may vary according to a target depth for an activation.

In the setting of the selective driving or the simultaneous driving, when at least partially crystallizing the target object, the selective driving of the first laser head unit may be set.

In the varying the wavelength of the first laser, the wavelength of the first laser may vary according to a target depth for a crystallization.

The laser annealing method may further include scanning the target object by moving the selected laser head unit, wherein the first laser head unit and the second laser head unit may be connected to a first laser source unit for generating the first laser and a second laser source unit for generating the second laser by optical fiber cables, respectively.

In the scanning of the target object, the target object may be scanned while moving the second laser head unit under different scan conditions for each area by dividing into a plurality of areas.

### Advantageous Effects

The laser annealing apparatus according to the embodiment of the present inventive concept may control the driving of the first laser head unit that irradiates the first laser and the second laser head unit that irradiates the second laser having the wavelength longer than that of the first laser so as to be applied to the non-melting process as well as the melting process. In addition, since the wavelength of the first laser is variable, the annealing may be performed on a target object (e.g., the substrate or the thin film) having various thicknesses, and the annealing depth may be adjusted.

Here, one or more of the first wavelength laser light source generating the first wavelength laser, the second wavelength laser light source generating the second wavelength laser, and the third wavelength laser light source generating the third wavelength laser may be selectively driven to vary in wavelength of the first laser, and thus, the wavelength of the first laser may vary not only to a single (light) wavelength but also to a mixed (light) wavelength. Therefore, not only the annealing depth may be adjusted, but also, the absorption of the laser may be promoted, and when using the mixed wavelength, the annealing process may be performed even with the relatively low output compared to the case in which the single wavelength is used.

In addition, the lasers (for example, the first laser and the second laser) may be transmitted to the first laser head unit and the second laser head unit through the first optical fiber cable and the second optical fiber cable to allow the first laser head unit and the second laser head unit to move, thereby scanning the target object. Accordingly, since the first laser head unit and the second laser head unit only need to move within the surface area of the processing area requiring the annealing on the target object, the space (foot-print) occupied by the equipment may be minimized.

The laser irradiation angle of the first laser head unit and the laser irradiation angle of the second laser head unit may be differently adjusted through the irradiation angle adjusting unit. In this manner, the problem such as the damage of the optical system, which may occur when the laser reflected from the surface of the target object is incident into the laser head unit that is different from the emitting laser head unit, may be prevented.

### BRIEF DESCRIPTION OF THE DRAWINGS

FIG. 1 is a perspective view illustrating a laser annealing apparatus according to an embodiment of the present inventive concept.

FIG. 2 is a conceptual view for explaining a configuration of a first laser source unit according to an embodiment of the present inventive concept.

FIG. 3 is a conceptual view for explaining simultaneous driving and selective driving of a first laser head unit and a second laser head unit according to an embodiment of the present inventive concept.

FIG. 4 is a conceptual view for explaining scanning of a first laser and a second laser in the simultaneous driving of the first laser head unit and the second laser head unit according to an embodiment of the present inventive concept.

FIG. 5 is a conceptual view for explaining an irradiation angle adjusting unit according to an embodiment of the present inventive concept.

FIG. 6 is a flowchart illustrating a laser annealing method according to another embodiment of the present inventive concept.

### MODE FOR CARRYING OUT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

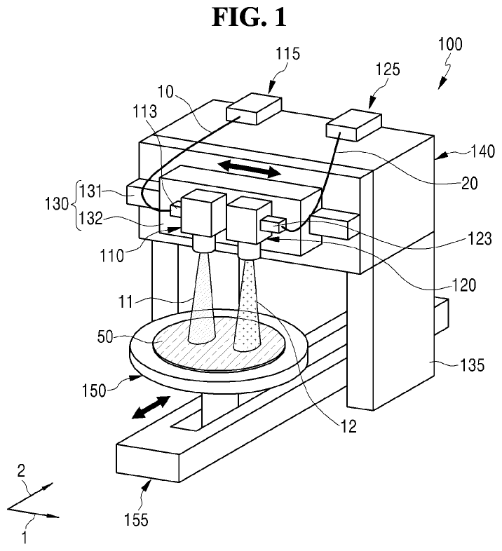

FIG. 1 is a perspective view illustrating a laser annealing apparatus according to an embodiment of the present inventive concept.

Referring to FIG. 1, a laser annealing apparatus 100 according to an embodiment of the present inventive concept may include: a stage 150 supporting a target object 50; a first laser head unit 110 connected to a first laser source unit 115 to irradiate a first laser 11 onto the target object 50; a second laser head unit 120 connected to a second laser source unit 125 to irradiate a second laser 12 having a wavelength longer than that of the first laser 11 onto the target object 50; and a control unit 140 controlling driving of the first laser head unit 110 and the second laser head unit 120.

The stage 150 may support the target object 50, and thus, the target object 50 such as a substrate 50a such as a silicon (Si) wafer or a semiconductor wafer, or a thin film 50b such as amorphous silicon (a-Si) may be seated horizontally on the stage 150. For example, the stage 150 may chuck and support the target object 50 through adsorption or adhesion. The stage 150 may include an electrostatic chuck (ESC) using electrostatic force or a plurality of vacuum suction ports for vacuum absorption and may include an adhesion layer for adhesion. Here, the stage 150 may support (or fix) the target object 50 during the annealing by irradiating the laser 11 or 12 to maintain the target object 50 at a predetermined horizontal position. The stage 150 may move by a stage driving unit 155 to move relative to the first laser head unit 110 and the second laser head unit 120. Here, the stage 150 may move in both directions of a first axis 1 and a second axis 2 and move only in a direction of any one axis 1 or 2 of the first axis 1 and the second axis 2. For example, the stage 150 may move in the direction of the second axis 2 as illustrated in FIG. 1. The stage 150 may include a heating unit that heats the target object 50.

The first laser head unit 110 may be connected to the first laser source unit 115 and may irradiate the first laser 11 to the target object 50. For example, the first laser head unit 110 may irradiate the first laser 11 provided (supplied) by the first laser source unit 115 onto the target object 50 supported on the stage 150 to anneal the target object 50.

Here, the first laser 11 may be a short-wavelength laser and may have a visible wavelength (about 380 nm to about 780 nm) or an almost visible wavelength (about 0.1 μm to about 1 μm). For example, the target object 50 may be a silicon (Si) wafer or a silicon (Si) thin film, and the first laser 11 may have a wavelength shorter than that a silicon (Si) bandgap wavelength (about 1.11 μm). Here, the first laser 11 may melt and crystallize the silicon (Si).

At this time, the first laser source unit 115 may provide the first laser 11 to the first laser head unit 110. Here, the first laser source unit 115 may directly generate the first laser 11 to transmit (or deliver) the first laser 11 to the first laser head unit 110. In addition, a raw laser (s) may be transmitted to the first laser head unit 110 so that the first laser 11 is generated in the first laser head unit 110 by the mixing or composing.

The wavelength may be an average wavelength or a wavelength spectrum, and the wavelength spectrum may indicate relative intensity according to a wavelength of light and may have one or more peak wavelengths. For example, the first laser 11 having a single wavelength may have one peak wavelength and a relatively narrow wavelength spectrum. Here, the first laser 11 having the mixed wavelength (or mixed light) may have two or more peak wavelengths according to the number of mixed light (or lasers), and the wavelength spectrum may be relatively wide.

The second laser head unit 120 may be connected to the second laser source unit 125 and may irradiate the second laser 12 having a wavelength longer than that of the first laser 11 to the target object 50. For example, the second laser head unit 120 may irradiate the second laser 1 supplied from the second laser source unit 125 to the target object 50 supported by the stage 150 may be annealed.

Here, the second laser 12 may be a long-wavelength laser and may have a wavelength longer than that of the first laser 11. For example, the second laser 12 may have an infrared wavelength (about 0.75 μm to about 1,000 μm) including a near infrared ray (about 0.75 μm to about 3 μm) and a far infrared ray (about 0.025 mm to about 1 mm) or a (mid) infrared ray having a wavelength (about 3 μm to about 25 μm) excluding the near infrared ray and the far infrared rays. Here, the peak wavelength of the second laser 12 may be longer than the (maximum) peak wavelength of the first laser 11, and the maximum peak wavelength may be a peak wavelength having the greatest (or highest) relative intensity among the two or more peak wavelengths. Also, the (average) wavelength of the second laser 12 may be longer than the average wavelength of the first laser 11. For example, the target object 50 may be a silicon (Si) wafer or a silicon (Si) thin film, and the second laser 12 may have a wavelength longer than the silicon (Si) bandgap wavelength (about 1.11 μm) (for example, 1.2 μm to 10.6 μm). Here, the second laser 12 may activate a dopant introduced (or implanted) into silicon (Si).

In this case, the second laser source unit 125 may supply the second laser 12 to the second laser head unit 120 and generate the second laser 12 to be transmitted to the second laser head unit 120. For example, the second laser source unit 125 may generate and emit (or oscillate) the second laser 12 through infrared lasers emitting infrared having a wavelength of 1.3 μm or 1.06 μm (Nd-YAG or Ndglass laser), 2.8 μm (HF laser), 5 μm (CO laser), 10.6 μm (CO2 laser), 16 μm (SF6 laser) or infrared laser such as H2O, D2O, HCN, and ethanol laser that oscillate far-infrared rays having wavelengths of tens to hundreds of μm. Particularly, the second laser source unit 125 may include trillium laser (TRL) and may irradiate the second laser 12 having a wavelength of about 2 μm. The trillium laser (TRL) may be configured by compacting a beam transmission optical system relative to a conventional CO2 laser that is mainly used as an infrared laser.

The control unit 140 may control driving of the first laser head unit 110 and the second laser head unit 120 and also may control not only movement of the first laser head unit 110 and the second laser head unit 120 but also an on/off of the lasers 11 and 12 irradiated from the first laser head unit 110 and the second laser head unit 120. For example, the control unit 140 may control the driving of the first laser head unit 110 and the second laser head unit 120 so that the first laser 11 and the second laser 12 overlap each other to move at the same time on the target object 50. In addition, the control unit 140 includes the driving of the first laser head unit 110 and the second laser head unit 120 so that only one laser 11 or 12 of the first laser 11 and the second laser 12 is scans the target object 50.

In this case, the on/off of the lasers 11 and 12 directly turns on/off each of the first laser source unit 115 and the second laser source unit 125 to turn on/off the first laser 11 and the second laser 12, respectively. In addition, the first laser 11 and the second laser 12 may be blocked by a shutter or the like so that the first laser 11 and the second laser 12 are not irradiated from the first laser head unit 110 or the second laser head unit 120.

The first laser head unit 110 and the second laser head unit 120 may be supported side by side on a gantry-shaped head support 135 to move in an extension direction of the head support 135 within the head support 135. In addition, the control unit 140 may be mounted on the head support 135.

The laser annealing apparatus 100 according to the present inventive concept may control the driving of the first laser head unit 110 that irradiates the first laser 11 and the second laser head unit that irradiates the second laser 12 through the control unit 140 and thus may be applied to a non-melting process such as the impurity activation as well as the melting process such as the crystallization.

Here, the wavelength of the first laser 11 may be variable by the control unit 140 and may be variable within a visible light wavelength or an almost visible light wavelength. For example, the control unit 140 may allow the wavelength of the first laser 11 to vary according to a thickness of the target object 50, and thus, the first laser 11 may reach a depth portion (or a region) from the surface of the target object 50 to anneal a surface of the target object 50. Also, the control unit 140 may allow the wavelength of the first laser 11 to vary according to the depth (or target depth) of the region to be annealed. Thus, the first laser 11 may reach a desired region for the annealing to the target depth within the thickness of the target object 50 to be annealed. When the wavelength of the first laser 11 is shortened, it is absorbed near the surface of the target object 50 to promote the annealing near the surface (region) of the target object 50. In addition, when the wavelength of the first laser 11 become longer, the first laser 11 may be absorbed to be penetrated relatively deeper so that the annealing is extended to the depth (or penetrated depth), or the annealing at the depth (region) is promoted.

Recently, it is necessary to form a shallow junction in PN junction according to a fine feature of a semiconductor device (size), and also, ultra-shallow junction is required. Since the laser having a fixed wavelength has a limit in adjusting a depth of the PN junction because the penetration depth of the laser is determined, the laser may be penetrated to an unintended depth to diffuse the impurities, thereby making it difficult to form the shallow junction. However, since the laser annealing apparatus 100 according to the present inventive concept allows the wavelength of the first laser 11 through the control unit 140 to vary within the visible light wavelength or the almost visible light wavelength (about 0.1 μm to about 1 μm), the wavelength of the first laser 11 may vary to adjust the depth of the PN junction. As a result, the shallow junction may be formed by shortening the wavelength of the first laser 11 to about 380 nm, or the ultra-shallow junction may be formed by very shorting the wavelength of the first laser 11 to about 100 nm. In addition, the wavelength of the first laser 11 may vary to perform the annealing up to (only) the target depth or at the target depth (region) to suppress or prevent leakage current from increasing in the semiconductor device due to an increase in diffusion of the impurities.

Therefore, the laser annealing apparatus 100 according to the present inventive concept may allow the wavelength of the first laser 11 to vary, thereby performing the annealing of the target object 50 such as the substrate 50a or the thin film 50b having various thicknesses and adjusting the depth of the annealing within the thickness of the target object 50.

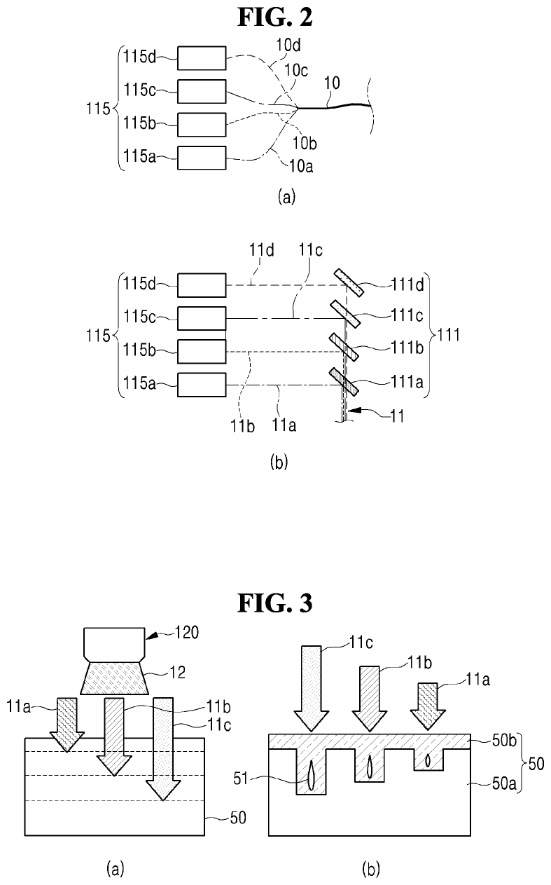

FIG. 2 is a conceptual view for explaining a configuration of the first laser source unit according to an embodiment of the present inventive concept, in particular, (a) of FIG. 2 illustrates an integrated optical fiber cable method in which each optical fiber cable is integrated, and (b) of FIG. 2 illustrates a mirror coupling method with respect to lasers having each wavelength through each optical fiber cable.

Referring to FIG. 2, the first laser source unit 115 may include: a first wavelength laser light source 115a that generates a first wavelength laser 11a having a blue (B) wavelength band; a second wavelength laser light source 115b that generates a second wavelength laser 11b having a green (G) wavelength band; and a third wavelength laser light source 115c that generates a third wavelength laser 11c of a red (R) wavelength band.

The first wavelength laser source 115a may generate the first wavelength laser 11a having the blue (B) wavelength band and emit (or oscillate) a continuous wave (CW) or a pulsed laser. Here, the first wavelength laser 11a may have one peak wavelength (e.g., wavelength of about 465 nm). For example, the first wavelength laser light source 115a may be a semiconductor laser. Here, the first wavelength laser light source 115a may be a laser diode (LD) having a wavelength of about 380 nm to about 500 nm (or about 420 nm to about 460 nm) and a gallium (Ga) nitride (GaN) laser diode (LD) having a wavelength of about 414 nm. The first wavelength laser light source 115a may generate the first wavelength laser 11a having a wavelength of about 400 nm by using a second harmonic generation (SHG) laser as a blue laser. Also, the first wavelength laser light source 115a may generate the first wavelength laser 11a having a wavelength of about 500 nm from a continuous wave (CW) argon (Ar) laser.

The second wavelength laser light source 115b may generate the second wavelength laser 11b having the green (G) wavelength band and may emit a continuous wave (CW) or a pulsed laser. Here, the second wavelength laser 11b may have one peak wavelength (e.g., wavelength of about 545 nm or about 532 nm). For example, the second wavelength laser light source 115b may be a semiconductor laser such as a second harmonic generation (SHG) laser (e.g., a harmonic laser of a YAG laser) or a laser diode (LD) using a solid-state laser or the like. Here, the second wavelength laser light source 115b may generate a second wavelength laser 11b having a green wavelength (about 530 nm wavelength) from a frequency-doubled second harmonic Nd:YAG laser (wavelength of about 532 nm), Nd:YLF laser (wavelength of about 527 nm), or Yb:YAG laser (wavelength of about 515 nm). When the wavelength of the first wavelength laser 11a is shorter than a wavelength of 500 nm, the second wavelength laser light source 115b may generate the second wavelength laser 11b having the wavelength of about 500 nm from the continuous wave (CW) argon (Ar) laser.

The third wavelength laser light source 115c may generate the third wavelength laser 11c having the red (R) wavelength band and may emit a continuous wave (CW) or a pulsed laser. Here, the third wavelength laser 11c may have one peak wavelength (e.g., wavelength of about 635 nm or about 615 nm). For example, the third wavelength laser light source 115c may be a semiconductor laser and may generate a red third wavelength laser 11c having a wavelength of about 600 nm to about 810 nm (or about 615 nm) from a GaAs-based laser diode LD. In addition, the third wavelength laser light source 115c may generate a red third wavelength laser 11c corresponding to a wavelength of about 660 nm to about 780 nm based on GaAlAs and may generate a red third wavelength laser 11c having a wavelength band of about 632 nm based on helium-neon.

As necessary, the first laser unit 115 may further include an n-th wavelength laser light source 115d that generates an n-th wavelength laser 11d in addition to the first wavelength laser light source 115a, the second wavelength laser light source 115b, and the third wavelength laser light source 115c. Here, the number of n-th wavelength laser light sources 115d such as the fourth wavelength laser light source and the fifth wavelength laser light source is not particularly limited.

Here, the control unit 140 may selectively drive one or more of the first wavelength laser light source 115a, the second wavelength laser light source 115b, and the third wavelength laser light source 115c to allow the wavelength of the first laser 11 to vary. For example, the control unit 140 may select one of the first wavelength laser light source 115a, the second wavelength laser light source 115b, and the third wavelength laser light source 115c to allow the wavelength of the first laser 11 to vary to a single wavelength having one peak wavelength. In addition, the control unit 140 may selectively drive two or more of the first wavelength laser light source 115a, the second wavelength laser light source 115b, and the third wavelength laser light source 115c to mix two or more of the first wavelength laser 11a, the second wavelength laser 11b, and the third wavelength laser 11c with each other so that the wavelength of the first laser 11 varies to a mixed wavelength having two or more peak wavelengths.

Here, when lasers having two wavelengths (e.g., a first wavelength and a second wavelength, a first wavelength and a third wavelength, or a second wavelength and a third wavelength) among the first wavelength laser 11a, the second wavelength laser 11b, and the third wavelength laser 11c are mixed with each other, the wavelength of the first laser 11 may vary to a mixed wavelength having two peak wavelengths. In addition, when all of the first wavelength laser 11a, the second wavelength laser 11b, and the third wavelength laser 11c are mixed with each other, the wavelength of the first laser 11 may vary to a mixed wavelength having three peak wavelengths. For example, when the first wavelength laser 11a and the second wavelength laser 11b are mixed with each other, the mixed wavelength laser may have two peak wavelengths of the first wavelength and the second wavelength, and when the first wavelength laser 11a and the third wavelength laser 11c are mixed with each other, the mixed wavelength laser may have two peak wavelengths of the first wavelength and the third wavelength. In addition, when the second wavelength laser 11b and the third wavelength laser 11c are mixed with each other, the mixed wavelength laser may have two peak wavelengths of the second wavelength and the third wavelength, and all of the first wavelength laser 11a, the second wavelength laser 11b, and the third wavelength laser 11c are mixed with each other, the mixed wavelength laser may have three peak wavelengths of the first wavelength, the second wavelength, and the third wavelength. As described above, the number of peak wavelengths and the wavelength spectrum may be different due to the mixing of the two or more of the first wavelength laser 11a, the second wavelength laser 11b, and the third wavelength laser 11c, and thus, a relative intensity for each wavelength may vary. Therefore, as a color coordinate position is changed, color characteristics of the first laser 11 (or the mixed light) may be changed.

Two or more of the first wavelength laser 11a, the second wavelength laser 11b, and the third wavelength laser 11c may be synthesized to have a wide wavelength band (or spectrum) such as white light rather than a specific wavelength. In addition, when the first laser source unit 115 further includes an n-th wavelength laser light source 115d, the control unit 140 may selectively drive one or more of the first to n-th wavelength laser light sources 115a, 115b, 115c, and 115d to allow the wavelength of the first laser 11 to vary. In addition, the first wavelength laser light source 115a, the second wavelength laser light source 115b, and the third wavelength laser light source 115c may have different pulse intervals while emitting the pulsed lasers, and the first wavelength laser light 11a, the second wavelength laser 11b and the third wavelength laser 11c may be irradiated onto the target object 50 with a time difference. In addition, the first laser source unit 115 and the second laser source unit 125 may emit pulsed lasers having different pulse intervals, and the first laser 11 and the second laser 12 may be emitted to the target object 50 with a time difference.

Therefore, the laser annealing apparatus 100 according to the present inventive concept may selectively drive one or more of the first wavelength laser light source 115a that generates the first wavelength laser 11a, the second wavelength laser light source 115b that generates the second wavelength laser 11b, and the third wavelength laser light source 115c that generates the third wavelength laser 11c to allow the wavelength of the first laser 11 to vary, and thus, the wavelength of the first laser 11 may vary in the mixed (light) wavelength as well as the single (light) wavelength. Thus, the annealing depth (or penetration depth) may be adjusted, and the absorption of the first laser 11 and/or the second laser 12 may be promoted. In addition, when using the mixed wavelength, in the first laser source unit 115 and/or the second laser source unit 125 (or at least one of the first wavelength laser light source, the second wavelength laser light source, or the third wavelength laser light source), the annealing process may be performed at a relatively low output compared to the case of using the single wavelength.

The control unit 140 may control the first wavelength laser light source 115a among the first wavelength laser light source 115a, the second wavelength laser light source 115b, and the third wavelength laser light source 115c to be always driven. The first wavelength laser 11a generated from the first wavelength laser light source 115a may have a short wavelength in the blue (B) wavelength band, and thus, an absorption rate may be high, and the penetration depth may be shallow. Therefore, the impurities may be effectively activated as well as may not affect the increase in diffusion of the impurities. On the other hand, each of the second wavelength laser 11b and the third wavelength laser 11c may have a wavelength longer than that of the first wavelength laser 11a so that the penetration depth is relatively deep, but the absorption rate is relatively low. Thus, as the target depth increases, the activation of the impurities may not be effective. However, in the case of irradiating the first wavelength laser 11a together even in the annealing of the deep target depth using the second wavelength laser 11b and/or the third wavelength laser 11c, the absorption rate (e.g., the absorption rate of the second wavelength laser and/or the third wavelength laser) may increase by the first wavelength laser 11a. Thus, when compared to the case of the single irradiating only the second wavelength laser 11b or the third wavelength laser 11c, in the first laser source unit 115 (or the first wavelength laser, the second wavelength laser and/or the third wavelength laser), the annealing may be performed even with a relatively low output.

Here, the impurity may be activated by activation energy such as bandgap energy (Eg), and minimum power Pthreshold or a threshold voltage Vthreshold for supplying the activation energy to the impurities may be required. The first wavelength laser 11a may compensate the absorption rate of the second wavelength laser 11b and/or the third wavelength laser 11c, and when the annealing is required through the second wavelength laser 11b and/or the third wavelength laser 11c for a relatively deep depth, the minimum power Pthreshold or the minimum voltage Vthreshold applied to the first laser source unit 115 may be reduced.

The laser annealing apparatus 100 according to the present inventive concept may further include: a head moving unit 130 that moves the first laser head unit 110 and the second laser head unit 120; a first optical fiber cable 10 provided between the first laser source unit 115 and the first laser head unit 110; and a second optical fiber cable 20 provided between the second laser source unit 125 and the second laser head unit 120.

The head moving unit 130 may move the first laser head unit 110 and the second laser head unit 120, and the first laser head unit 110 and the second laser head unit 120 may be independently moved. Here, the head moving unit 130 may move each of the first laser head unit 110 and the second laser head unit 120 in both the directions of the first axis 1 and the second axis 2. In addition, the head moving unit 130 may move each of the first laser head unit 110 and the second laser head unit 120 in a direction of any one 1 or 2 of the first axis 1 and the second axis 2, for example, in the direction of the first axis 1 as illustrated in FIG. 1.

For example, the head moving unit 130 may include a rail 131 provided on the head support 135 and a movable body 132 to which the first laser head unit 110 and the second laser head unit 120 are fixed (or supported) to be moved (slid) along the rail 131. The rail 131 may be installed and provided on the head support 135 and may extend in at least one direction to guide (or provide) a movement path of the movable body 132 in the at least one direction. Here, the rail 131 may have a linear structure or a closed racetrack structure such as a circular or elliptical shape.

In the movable body 132, the first laser head unit 110 and the second laser head unit 120 may be fixed (or supported) and may be moved along the rail 131. Here, the movable body 132 may be provided in plurality (pieces), and the first laser head unit 110 and the second laser head unit 120 are respectively fixed to the respective movable bodies 132 to be moved independently. Here, when the rail 131 has the linear structure, the movable body 132 may be reciprocated (or moved) in the extension direction (or the one direction) of the rail 131 along the rail 131, and when the rail 131 has the racetrack structure, the movable body 132 may be circulated (or moved) along the rail 131.

The first optical fiber cable 10 may be provided between the first laser source unit 115 and the first laser head unit 110, and the first laser 11 may be provided (supplied) to the first laser head unit 110. Here, the first optical fiber cable 10 may transmit (or deliver) the first laser 11 generated in the first laser source unit 115 to the first laser head unit 110. In addition, the first optical fiber cable 10 may transmit each of the first wavelength laser 11a, the second wavelength laser 11b, and the three wavelength laser 11c to the first laser head unit 110 so that the first laser 11 is generated in the first laser head unit 110 by mixing or synthesizing.

For example, the first optical fiber cable 10 may be constituted by unit cables 10a, 10b, 10c, and 10d that transmit the first wavelength laser 11a, the second wavelength laser 11b, and the third wavelength laser 11c, respectively, as illustrated in (a) of FIG. 2. In addition, the first optical fiber cable 10 may be provided by mixing (or synthesizing) the first wavelength laser 11a, the second wavelength laser 11b, and the third wavelength laser 11c as illustrated in (b) of FIG. 2. Here, the first optical fiber cable 10 may transmit the first wavelength laser 11a, the second wavelength laser 11b, and the third wavelength laser 11c, respectively, and the first wavelength laser 11a, the second wavelength laser 11b, and the third wavelength laser 11c may be mixed by a mirror unit 111 and then be emitted (or irradiated) from the first laser head unit 110, or the first laser mixed by the mirror unit 111 may be transmitted to the first laser head unit 110.

Here, the mirror unit 111 may include a first mirror 111a, a second mirror 111b, and a third mirror 111c. The first mirror 111a may reflect the first wavelength laser 11a and transmit lasers having different wavelengths (e.g., the second wavelength laser and the third wavelength laser, etc.). In addition, the second mirror 111b may reflect the second wavelength laser 11b and transmit lasers of different wavelengths (e.g., the first wavelength laser and the third wavelength laser, etc.). In addition, the third mirror 111c may reflect the third wavelength laser 11c and transmit lasers of different wavelengths (e.g., the first wavelength laser and the second wavelength laser, etc.). In addition, the mirror unit 111 may further include an n-th mirror 111d as necessary, and the n-th mirror 111d may reflect the n-th wavelength laser 11d and transmit lasers having different wavelengths (e.g., the first wavelength laser, the second wavelength laser, the third wavelength laser, etc.).

Here, the first optical fiber cable 10 may be connected to the first laser head unit 110 by a first connector 113. The first connector 113 may include a collimator that collects the first laser 11 from the first optical fiber cable 10 to deliver (or transmit) the first laser 11 to the first laser head unit 110, and a mirror unit 111 may be provided on the first connector 113.

The second optical fiber cable 20 may be provided between the second laser source unit 125 and the second laser head unit 120, and the second laser 12 generated by the second laser source unit 125 may be transmitted to the second laser head unit 120. In this case, the second optical fiber cable 20 may be connected to the second laser head unit 120 by the second connector 123. The second connector 123 may include a collimator that collects the second laser 12 from the second optical fiber cable 20 to deliver the second laser 12 to the second laser head unit 120.

According to the related art, be a laser may transmitted using only a beam delivery optical system, and when the laser head is moved due to the fixed installation of the beam delivery optical system, the beam alignment of the laser may be misaligned, or movement of the laser head unit may be limited by a beam path housing that fixes the laser head unit while providing a beam path.

However, since the first optical fiber cable 10 and the second optical fiber cable 20 have ductility or flexibility, the movement of the first laser head unit 110 and the second laser head unit 120 may not be limited, and the first laser head unit 110 and the second laser head unit 120 may be moved freely. Thus, each of the first laser head unit 110 and the second laser head unit 120 may be moved not only in the direction of the first axis 1 but also in the direction of the second axis 2. That is, the stage 150 may not be moved for scanning, and the first laser head unit 110 and the second laser head unit 120 may be moved within only the surface area of the processing area requiring the annealing on the target object 50. The first optical fiber cable 10 and the second optical fiber cable 20 are not only inexpensive and small in size, but also effectively transmit each laser (e.g., the first laser and the second laser) to realize sufficient beam quality that satisfies process quality. In addition, the first optical fiber cable 10 and the second optical fiber cable 20 may improve design flexibility of the laser annealing apparatus 100, a space (foot-print) occupied by y equipment may be minimized, maintenance costs may be reduced when compared to the (conventional) beam delivery optical system.

In addition, when moving the first laser head unit 110 and the second laser head unit 120 instead of the stage 150, a process time may be reduced compared to the method of moving the (conventional) stage 150, and it may be efficient because (only) the machining area, on which the annealing is required, is selectively annealed.

Furthermore, the first fiber optic cable 10 and the second fiber optic cable 20 may require very low (or little) maintenance except for errors due to electrical aging and be used last for 5 to 10 years. Thus, it has an advantage in terms of uptime compared to the (conventional) beam delivery optical system. In addition, since the first optical fiber cable 10 and the second optical fiber cable 20 may use the continuous wave (CW) laser having the relatively low peak power compared to the pulsed laser, a temperature deviation between the irradiation (spot) of the laser may not be large, and thus, temperature uniformity through driving (or movement) of the first laser head unit 110 and/or the second laser head unit 120 may be secured. In addition, the first laser 11 and the second laser 12 collimated through the first optical fiber cable 10 and the second optical fiber cable 20 may be transmitted to the first laser head unit 110 and the second laser unit, and thus, a separate optical configuration such as a reflection mirror may not be required.

Therefore, in the laser annealing apparatus 100 according to the present inventive concept, the first optical fiber cable 10 and the second optical fiber cable 20 may connect the first laser source unit 115 to the first laser head unit 110 and connect the second laser source unit 125 to the second laser head unit 120, and thus, each laser (for example, the first laser and the second laser) may be effectively provided (or transmitted) to the first laser head unit 110 and the second laser head unit 120, respectively, and the first laser head unit 110 and the second laser head unit 120 may be moved to scan the target object 50. Thus, since the first laser head unit 110 and the second laser head unit 120 only need to be moved within the surface area of the processing area on which the annealing is required on the target object 50, the space occupied by the equipment may be minimized.

The head support 135 may be moved in the direction of the second axis 2 to move the first laser head unit 110 and the second laser head unit 120 in the direction of the second axis 2. For example, the first laser head unit 110 and the second laser head unit 120 are moved in the direction of the first axis 1 through the rail 131 and the movable body 132, and the head support 135 may be moved in the direction of the second axis 2 to move the first laser head unit 110 and the second laser head unit 120 in the direction of the second axis 2. In this case, a length of the rail 131 may be reduced (or minimized), and the target object 50 may be scanned without moving the stage 150. Thus, since the first laser head unit 110 and the second laser head unit 120 only need to be (relatively) moved within the surface area of the processing area on which the annealing is required on the target object 50, the space occupied by the equipment may be minimized.

FIG. 3 is a conceptual view for explaining simultaneous driving and selective driving of the first laser head unit and the second laser head unit according to an embodiment of the present inventive concept, in particular, (a) of FIG. 3 illustrates simultaneous driving of the first laser head unit and the second laser head unit, and (b) of FIG. 3 illustrates selective driving of the first laser head unit.

Referring to FIG. 3, the control unit 140 may control in a selective driving of any one of the first laser head unit 110 and the second laser head unit 120 or a simultaneous driving of the first laser head unit 110 and the second laser head unit 120. The control unit 140 may drive only the first laser head unit 110 or only the second laser head unit 120 or simultaneously drive the first laser head unit 110 and the second laser head unit 120.

For example, for the melting process such as the crystallization, the first laser head unit 110 may be driven to irradiate the first laser 11 having a relatively short wavelength, and for the non-melting process such as the impurity activation, the second laser head unit 120 may be driven to irradiate the second laser 12 having a relatively long wavelength.

Here, when activating the impurities, the first laser head unit 110 and the second laser head unit 120 may be driven simultaneously, and after the first laser head unit 110 generates free electrons or free carriers by the first laser 11, the second laser head unit 120 may irradiate the second laser 12 to activate the impurities.

That is, since the second laser 12 is transmitted without being absorbed into the target object 50 with a long wavelength, the free electrons or the free carriers are formed in the target object 50 through the first laser 11 to increase in absorption rate of the second laser 12.

According to the related art, although a heating unit of the stage 150 is used as a method for forming the free carriers for the internal absorption of the target object 50, but in the present inventive concept, the free carriers are formed through the first laser 11, and thus, the heating unit may not be required for the stage 150. For example, the second laser 12 may be a laser having a wavelength (e.g., a long wavelength), which has energy less than the silicon (Si) band gap energy (about 1.2 eV) and may be generally transmitted without being absorbed into the silicon (Si). For this reason, absorption rate of the second laser 12 may increase by forming the free electrons on the surface of the semiconductor (i.e., the target object) through the first laser 11 having a wavelength of visible light (e.g., RGB).

In the PN junction, the shallow junction may be formed by adjusting the wavelength of the first laser 11 to be shortened to about 380 nm, or ultra-shallow junction may be formed by very shorting the wavelength of the first laser 11 to about 100 nm. When the laser is penetrated to an unintentional depth in the thin film transistor (TFT) to cause excessive diffusion of the impurities, leakage current may occur in the thin film transistor TFT, which may cause a connection failure between a source and a drain. However, in the present inventive concept, the wavelength of the first laser 11 may vary to perform the annealing up to (only) the target depth or at the target depth (region). Thus, the leakage current may be suppressed or prevented from increasing in the semiconductor device due to an increase in diffusion of the impurities to prevent the connection failure between the source and the drain in the thin film transistor (TFT).

In the process of forming the thin film 50b on the substrate 50a during the manufacturing of the semiconductor device, as illustrated in (b) of FIG. 3, a void 51 may be generated due to the step coverage, and the void 51 within the thin film 50b, which may cause deterioration of device characteristics, may be removed through the melting process. In addition, the first laser 11 may be irradiated to re-crystallize the thin film 50b or realize defect curing.

Here, the wavelength of the first laser 11 may be adjusted to adjust the penetration depth (or the annealing depth) to remove the void 51 within the target object 50 (i.e., within the thin film) regardless of a depth in which the void 51 is formed. For example, as illustrated in (b) of FIG. 3, the void 51 that is close to the surface of the thin film 50b may be removed by irradiating the first wavelength laser 11a, and the void 51 having an intermediate depth a little far from the surface of the thin film 50b may be removed by irradiating the second wavelength laser 11b. In addition, the void 51 disposed at a deep position in the thin film 50b may be removed by irradiating the third wavelength laser 11c.

Therefore, the laser annealing apparatus 100 according to the present inventive concept may control the first laser head unit 110 and the second laser head unit 120 in the selective driving or the simultaneous driving through the control unit 140 and thus may be selectively applied to the impurity activation process as well as the crystallization process.

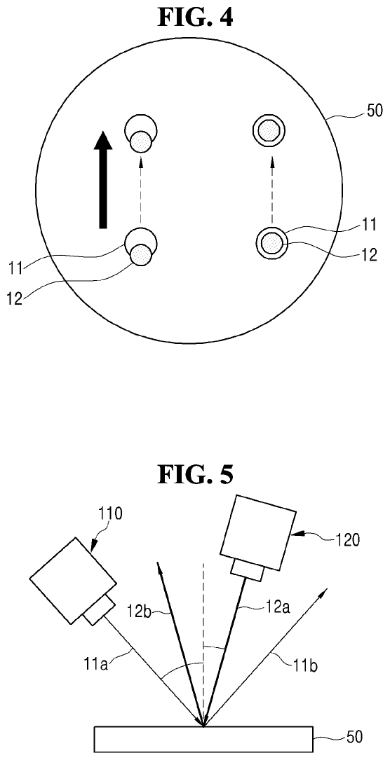

FIG. 4 is a conceptual view for explaining scanning of the first laser and the second laser in the simultaneous driving of the first laser head unit and the second laser head unit according to an embodiment of the present inventive concept.

Referring to FIG. 4, a beam size of the first laser 11 may be greater than or equal to a beam size of the second laser 12 in the simultaneous driving of the first laser head unit 110 and the second laser head unit 120. Here, a beam shape of the first laser 11 may be a linear beam or a spot beam and may have a Gaussian or top hat shape. In addition, a beam shape of the second laser 12 may also be a linear beam or a point beam and may have a Gaussian or top hat shape. Here, the beam size of the first laser 11 may be several tens of μm to several mm, and the beam size of the second laser 12 may also be several tens of μm to several mm. That is, after the first laser 11 may be irradiated to generate the free electrons or the free carriers, the second laser 12 may be irradiated. When the beam size of the second laser 12 is larger than the beam size of the first laser 11 in the simultaneous driving of the first laser head unit 110 and the second laser head unit 120, a region (or a region larger than the first laser) that does not overlap the first laser 11 and deviates from the first laser 11 is present. In this manner, the free electrons or the free carriers may not be generated in the region outside the first laser 11, and thus, the second laser 12 may not be absorbed, and the impurities may not be activated.

Thus, in the simultaneous driving of the first laser head unit 110 and the second laser head unit 120, the beam size of the first laser 11 may be set to be equal to or greater than that of the second laser 12, and after the free electrons or the free carriers are generated, the second laser 12 may be irradiated.

The beam size of the first laser 11 may be set to be less than or equal to the beam size of the second laser 12 according to circumstances (e.g., a case in which the first laser is preceded, etc.).

In addition, the control unit 140 may control the scanning of the first laser head unit 110 and the second laser head unit 120 in the simultaneous driving of the first laser head unit 110 and the second laser head unit 120 so that the first laser 11 and the second laser 12 overlap each other, or the first laser 11 is disposed in front of the second laser 12 in the scan direction. That is, the first laser 11 and the second laser 12 may be simultaneously irradiated to the annealing target position, or the first laser 11 may be preceded and irradiated before the second laser 12.

When the second laser 12 is disposed in front of the first laser 11 in the scan direction, the second laser 12 may precede the first laser 11 at each position, and in a state in which the free electrons or the free carriers are not generated, the second laser 12 may be irradiated, and thus, the second laser 12 may not be absorbed, and the impurities may not activated. Thus, in the simultaneous driving of the first laser head unit 110 and the second laser head unit 120, after the first laser 11 is simultaneously with the second laser 12 or precedes the second laser 12 so that the first laser 11 is irradiated to the annealing target position to generate the free electrons or the free carriers, the second laser 12 may be irradiated.

FIG. 5 is a conceptual view for explaining an irradiation angle adjusting unit according to an embodiment of the present inventive concept.

Referring to FIG. 5, the laser annealing apparatus 100 according to the present inventive concept may further include an irradiation angle adjusting unit (not shown) that adjusts each of a laser irradiation angle of the first laser head unit 110 and a laser irradiation angle of the second laser head unit 120.

The irradiation angle adjusting unit (not shown) may adjust each of the laser irradiation angle of the first laser head unit 110 and the laser irradiation angle of the second laser head unit 120, respectively, and the laser irradiation angle of the first laser head unit 110 and the laser irradiation angle of the second laser head unit 120 may be different from each other. Here, the irradiation angle adjusting unit (not shown) may adjust the laser irradiation angle by tilting each of the first laser head unit 110 and the second laser head unit 120. In addition, the irradiation angle adjusting unit (not shown) may adjust the laser irradiation angle by a galvanometer mirror or polygon mirror, which is provided inside each of the first laser head unit 110 and the second laser head unit 120. The laser irradiation angle of the first laser head unit 110 and the laser irradiation angle of the second laser head unit 120 may be adjusted so that the first laser 11 and the second laser 12 at least partially overlap each other, and the first laser 11 and/or the second laser 12, which are irradiated, scan the target object 50.

In addition, when the laser irradiation angle of the first laser head unit 110 and the laser irradiation angle of the second laser head unit 120 are the same, the lasers 11a and 12a respectively irradiated from the laser head units 110 and 120 may be reflected from the surface of the target object 50, and the reflected lasers 11b and 12b may be incident to the other laser head units 120 and 110. As a result, an optical system of each of the laser head units 110 and 120 may be damaged. Thus, the laser annealing apparatus 100 according to the present inventive concept may differently adjust the laser irradiation angle of the first laser head unit 110 and the laser irradiation angle of the second laser head unit 120 through the irradiation angle adjusting unit (not shown). Through this, the problem such as the damage of the optical system, which may occur when the laser 11 or 12 reflected from the surface of the target object 50 is incident into the laser head unit 120 or 110, which is different from the emitting laser head unit 110 or 120, may be prevented.

The control unit 140 may control the scanning of the second laser head unit 120 by dividing into a plurality of areas and using different scan conditions for each area. Here, the plurality of areas may have different scan conditions and may include a first area and a second area having different scan conditions.

For example, the target object 50 may be divided into the plurality of areas, and also, the first area may be a pre-heating area for preheating the target object 50, and the second area may be a normal area on which normal scanning is performed. In the case of activating the target object 50 through the scanning of the second laser head unit 120, a temperature of the target object 50 supported by the stage 150 before the irradiation of the second laser 12 (e.g., for example, 400° C.) requires predetermined energy to rise to an activation temperature (e.g., 1,200° ° C. For the predetermined energy (or predetermined accumulated energy), the irradiation of the second laser 12 to the target object 50 may start, and thus, a predetermined time may be required. When the target object 50 is scanned with the laser 11 or 12, heat of the portion immediately irradiated with the laser 11 or 12 may be transferred (or diffused) along a scan line. After the predetermined time, the portion (or region) that is irradiated with the second laser 12 and scanned while the heat of the portion raised to the activation temperature is transferred along the scan line by being irradiated with the second laser 12 may be continuously activated by being raised up to the activation temperature. Here, the predetermined time means a time other than 0 second, i.e., may be several seconds (s), several milliseconds (ms), several microseconds (μs), several nanoseconds (ns), several picoseconds (ps), several femtoseconds (fs), several attoseconds (as), zeptoseconds (zs), several yoctoseconds (ys), and the like, and it is sufficient if it is greater than 0 second. In this case, as the energy of the second laser 12 increases, the predetermined energy may reach faster, and the predetermined time may be shortened.

When normal scanning is performed as in the general area from a time point at which the second laser 12 is irradiated to the target object 50, the temperature of the target object 50 may not be raised up to the activation temperature on an area (or portion) on which the scan is performed before the predetermined time reaches the activation temperature, and thus, the activation may not be performed. For this reason, the activation is performed only on the area scanned from the predetermined time (e.g., from about 14 mm after the irradiation start point of the second laser). In this case, it is impossible to use (or utilize) the portion at which the target object 50 is not activated.

Therefore, after starting the irradiation of the second laser 12 to the first area as a preheating area and scanning for more than the predetermined time (sufficient), the second area may be scanned through the normal scanning from the time point when the predetermined time has elapsed (or the time point longer than the predetermined time). Thus, the entire target object 50 may be activated, and the entire activated target object 50 may be utilized (or used).

Here, the scan conditions may be a scan speed, the number of times of scanning, a spaced width between the scan lines parallel to each other (or an overlapping width of a laser beam between the scan lines parallel to each other), and an amount of energy accumulated by the second laser 12 per unit area. For example, the first area may be scanned for a period of time longer than the predetermined time by scanning the first area at a scan speed that is slower than that of the second area or by increasing in number of times of scanning on the first area rather than that of the second area. As a result, the amount of energy accumulated by the second laser 12 per unit area on the first area may be greater than that of the second area. Here, the spaced width between scan lines parallel to each other on the first area may be set to be less than that on the second area, or the overlapping width of the (laser) beam (or the second laser beam) between the scan lines parallel to each other may be set to be greater than that on the second area so that the amount of energy accumulated by the second laser 12 per unit area on the first area is greater than that on the second area.

In addition, a surface area of the first area may be set to be less than that of the second area, and it is preferable that a width of the first area in a direction crossing the extension direction of the scan line is the same a width (i.e., a width in a direction crossing the extension direction of the scan line) of the beam of the second laser 12. Since the first area needs to be scanned for a long time, as the surface area of the first area increases, the overall process time for activating the entire target object 50 increases. Thus, the width of the first area in the direction crossing the extension direction of the scan line may be set to be equal to the width of the beam of the second laser 12 so that the first area is reciprocally scanned using the beam of the second laser 12 only for the predetermined time period, and then, the second area is scanned immediately after the predetermined time period. In this case, since the energy by the second laser 12 is accumulated in almost the same area until the predetermined time, the activation of the entire area of the target object 50 may be ensured without the portion of the first area, which is not activated.

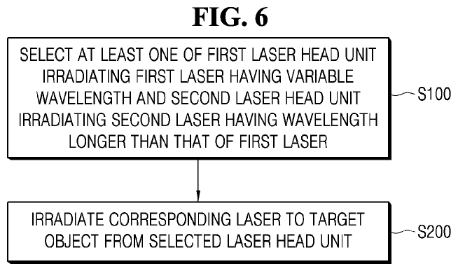

FIG. 6 is a flowchart illustrating a laser annealing method according to another embodiment of the present inventive concept.

A laser annealing method according to another embodiment of the present inventive concept will be described with reference to FIG. 6. In the description of the laser annealing method according to another embodiment of the present inventive concept, duplicated descriptions with respect to the foregoing laser annealing apparatus will be omitted.

The laser annealing method according to another embodiment of the present inventive concept may include: a process of selecting at least one laser head unit of a first laser head unit that irradiates a first laser having a variable wavelength and a second laser head unit that irradiates a second laser having a wavelength greater than that of the first laser; and a process of irradiating a laser corresponding to each laser head unit of the first laser and the second laser to a target object from the laser head unit selected from the first laser head unit and the second laser head unit.

First, at least one laser head unit is selected from among the first laser head unit that irradiates the first laser having the variable wavelength and the second laser head unit that irradiates the second laser having the wavelength longer than that of the first laser (S100). At least one of the first laser head unit and the second laser head unit may be selected through a control unit. In a melting process such as crystallization, the first laser head unit may be selected to irradiate the first laser having a relatively short wavelength. In a non-melting process such as impurity activation, the second laser head unit may be selected to irradiate the second laser having a wavelength longer than that of the first laser. Here, the first laser may have a variable wavelength, may be variable to a single wavelength while changing in position of one peak wavelength, or may be variable to a mixed wavelength in which two or more peak wavelengths are mixed with each other.

Next, the laser head unit selected from the first laser head unit and the second laser head unit irradiates a laser corresponding to each laser head unit among the first laser and the second laser to the target object (S200). The laser head unit selected from the first laser head unit and the second laser head unit may irradiate a laser corresponding to each laser head unit among the first laser and the second laser to the target object, and annealing of the melting process or the non-melting process may be performed on the target object.

Thus, the first laser head unit and the second laser head unit may be selectively driven to perform the melting process and the non-melting process through one laser annealing apparatus.

The laser annealing method according to the present inventive concept may further include a process of varying the wavelength of the first laser, by selectively driving one or more of a first wavelength laser light source that generates a first wavelength laser having a blue wavelength band, a second wavelength laser light source that generates a second wavelength laser having a green wavelength band and a third wavelength laser light source that generates a third wavelength laser having a red wavelength band.

One or more of the first wavelength laser light source that generates the first wavelength laser having the blue (B) wavelength band, the second wavelength laser light source that generates the second wavelength laser having the green (G) wavelength band, and the third wavelength laser light source that generates the third wavelength laser having the red (R) wavelength band may be selectively driven to allow the wavelength of the first laser to be vary (S50). A first laser source unit may include a first wavelength laser light source, a second wavelength laser light source, and a third wavelength laser light source, and the control unit may control the first laser source unit so that the first wavelength laser light source, the second wavelength laser light source, and the third wavelength laser light source are selectively driven.

For example, the control unit may selectively drive one or more of the first wavelength laser light source, the second wavelength laser source, light and third wavelength laser light source to allow the wavelength of the first laser to vary. In this case, one of the first wavelength laser light source, the second wavelength laser light source, and the third wavelength laser light source may be selected to allow the wavelength of the first laser to vary as a single wavelength. In addition, at least two or more of the first wavelength laser light source, the second wavelength laser light source, and the third wavelength laser light source may be selectively driven to mix two or more of the first wavelength laser, the second wavelength laser, and the third wavelength laser with each other, thereby allowing the wavelength of the first laser to vary as a mixed wavelength.

As a result, one or more of the first wavelength laser light source generating the first wavelength laser, the second wavelength laser light source generating the second wavelength laser, and the third wavelength laser light source generating the third wavelength laser may be selectively driven to vary in wavelength of the first laser, and thus, the wavelength of the first laser may vary not only to the single (optical) wavelength but also to the mixed (optical) wavelength. Thus, the annealing depth (or penetration depth) may be adjusted, and the absorption of the first laser and/or the second laser may be promoted. In addition, when using the mixed wavelength, in the first laser source unit and/or the second laser source unit (or at least one of the first wavelength laser light source, the second wavelength laser light source, or the third wavelength laser light source), the annealing process may be performed at a relatively low output compared to the case of using the single wavelength.

The laser annealing method according to the present inventive concept may further include a process (S60) of setting the driving of the first laser head unit and the second laser head unit to selective driving or simultaneous driving.

The driving of the first laser head unit and the second laser head unit may be set to the selective driving or the simultaneous driving (S60). The driving of the first laser head unit and the second laser head unit may be set to the selective driving or the simultaneous driving, and the first laser head unit and the second laser head unit may be selectively driven, or the first laser head unit and the second laser head unit may be simultaneously driven.

In the process (S100) of the selecting at least one laser head unit, the at least one laser head unit may be selected from the first laser head unit and the second laser head unit according to the set driving of the first laser head unit and the second laser head unit. In the selective driving, only the first laser head unit may be selected through the control unit to irradiate only the first laser, or only the second laser head unit may be selected to irradiate only the second laser. In the simultaneous driving, both the first laser head and the second laser head may be selected to irradiate both the first laser and the second laser.

In the process (S60) of setting the selective driving or the simultaneous driving, the simultaneous driving may be set when activating at least a portion of the target object. In the non-melting process such as the impurity activation, the second laser head may be driven to irradiate the second laser having a relatively long wavelength. Here, the first laser head unit and the second laser head unit may be simultaneously driven. After the first laser head unit generates free electrons or free carriers by the first laser, the second laser head unit may irradiate the second laser to activate impurities.

In the process (S60) of setting the selective driving or the simultaneous driving, when activating at least a portion of the target object, the selective driving of the first laser head unit may be set. The wavelength of the first laser may vary to adjust an activation depth, the free electrons or the free carriers may be generated by the first laser, and the impurities may be activated. For example, the free electrons or the free carriers may be generated by one or more of the first to n-th wavelength lasers (or the first wavelength laser, the second wavelength laser, and the third wavelength laser). In addition, the impurities may be activated by a laser having a relatively longer wavelength (e.g., a wavelength adjacent to near infrared rays) than a laser generating the free electrons or the free carriers among the first to n-th wavelength lasers.

In the process (S50) of the varying the wavelength of the first laser, the wavelength of the first laser may be variable according to a target depth for an activation. An annealing depth (or penetration depth) may vary according to the wavelength of the first laser, and as the wavelength increases, an absorption rate may decrease, and the penetration depth may increase. Thus, the wavelength of the first laser may be variable so that the impurities are activated up to the target depth for the activation, and the first laser may generate the free electrons or the free carriers up to the penetration depth (or the annealing depth). That is, the annealing depth may be determined according to the penetration depth corresponding to the variable (or selected) wavelength of the first laser, the free electrons or the free carriers may be generated up to the penetration depth, and the impurities may be activated. In this case, an intensity (or output) of the first laser may be determined by energy capable of generating the free electrons or the free carriers, and a beam size and scan speed may be determined according to the energy capable of generating the free electrons or the free carriers.

The laser annealing method according to the present inventive concept may further include: a process (S251) of generating the free carriers by the first laser; and a process (S252) of absorbing the second laser to activate the impurities in the target object.

The free carriers may be generated by the first laser (S251). Since the second laser is transmitted without being absorbed into the target object with a long wavelength, the free carriers may be generated by the first laser before the second laser is irradiated to increase in absorption rate of the second laser. That is, since the first laser head unit and the second laser head unit are simultaneously driven, the free carriers may be formed in the target object through the first laser to increase in absorption rate of the second laser. According to the related art, although a heating unit of a stage is used as a method for forming the free carriers for the internal absorption of the target object, but in the present inventive concept, the free carriers are formed through the first laser, and thus, the heating unit may not be required for the stage. For example, the second laser may be a laser having a wavelength (e.g., a long wavelength), which has energy less than the silicon (Si) band gap energy (about 1.2 eV) and may be generally transmitted without being absorbed into the silicon (Si). For this reason, the absorption rate of the second laser may increase by forming the free electrons on the surface of the semiconductor (i.e., the target object) through the first laser having a wavelength of visible light (e.g., RGB).

In addition, the impurities in the target object may be activated by absorbing the second laser (S252). The second laser may be irradiated after the free carriers are generated in the target object through the first laser, and thus, the second laser may be absorbed to activate the impurities in the target object. That is, in the simultaneous driving of the first laser head unit and the second laser head unit, the first laser may be irradiated to an annealing target position by performing the first laser simultaneous with the second laser or preceding the second laser so that the first laser is freely irradiated, and after the carrier is generated, the second laser may be irradiated. Thus, the impurities in the target object may be activated by absorbing the second laser.

The laser annealing method according to the present inventive concept may further include a process (S70) of adjusting each of a laser irradiation angle of the first laser head unit and a laser irradiation angle of the second laser head unit.

Each of the laser irradiation angle of the first laser head unit and the laser irradiation angle of the second laser head unit may be adjusted (S70). Each of the laser irradiation angle of the first laser head unit and the laser irradiation angle of the second laser head unit may be adjusted through an irradiation angle adjusting unit. Through this, the first laser and the second laser may at least partially overlap each other, and the irradiated first laser and/or the irradiated second laser may scan the target object. In this case, the laser irradiation angle of the first laser head unit and the laser irradiation angle of the second laser head unit may be different from each other.

In the laser annealing method according to the present inventive concept, the laser irradiation angle of the first laser head unit and the laser irradiation angle of the second laser head unit may be differently adjusted through the irradiation angle adjusting unit, and thus, a problem such as the damage of an optical system, which may occur when each laser reflected from a surface of the target object is incident into the laser head unit different from the emitting laser head unit, may be prevented.

In the process (S60) of setting the selective driving or the simultaneous driving, when at least partially crystallizing the target object, the selective driving of the first laser head unit may be set. For the melting process such as the crystallization, the first laser head may be selectively driven to irradiate the first laser having a relatively short wavelength.

In the process (S50) of the varying the wavelength of the first laser, the wavelength of the first laser may be variable according to a target depth for a crystallization. An annealing depth (or penetration depth) may vary according to the wavelength of the first laser, and as the wavelength increases, an absorption rate may decrease, and the penetration depth may increase. Thus, the wavelength of the first laser can be variable so that the crystallization is performed up to (or at) a target depth for the activation, and the first laser may perform the crystallize up to (at) a penetration depth (or annealing depth). That is, the annealing depth may be determined according to the penetration depth corresponding to the wavelength of the variable (or selected) first laser, and the annealing may be performed up to (or at) the penetration depth so as to be melted, and a void of a thin film may be removed, or the thin film may be recrystallized (re-crystallized). Here, the intensity (or output) and energy of the first laser may be determined not to affect a lower structure while being above a melting threshold, and the beam size and scan speed may be determined according to the melting threshold.

Therefore, the laser annealing method according to the present inventive concept may be selectively applied to not only the crystallization process but also the impurity activation process by driving the first laser head unit and the second laser head unit at the selective driving or the simultaneous driving.

The laser annealing method according to the present inventive concept may further include a process (S250) of scanning the target object by moving the selected laser head.

The target object may be scanned by moving the selected laser head (S250). Each of the first laser head unit and the second laser head unit may be moved through a head moving unit, the target object may be scanned, and (only) a processing area requiring the annealing may be selectively annealed.

Here, the first laser head unit and the second laser head unit may be respectively connected to a first laser source unit for generating the first laser and a second laser source unit for generating the second laser by an optical fiber cable. Since the optical fiber cable has ductility or flexibility, the movement of the first laser head and the second laser head may not be restricted, and the first and second laser heads may be freely moved. Thus, each of the first laser head unit and the second laser head unit may be moved not only in a first axial direction but also in a second axial direction. That is, the stage may not be moved for scanning, and the first laser head unit and the second laser head unit may be moved within only the surface area of the processing area requiring the annealing on the target object. The optical fiber cable may be not only inexpensive and small in size, but also effectively transmit each laser (e.g., the first laser and the second laser) to realize sufficient beam quality that satisfies process quality. In addition, the optical fiber cable may improve design flexibility of the laser annealing apparatus, a space (foot-print) occupied by equipment may be minimized, maintenance costs may be reduced when compared to the (conventional) beam delivery optical system.

Therefore, in the laser annealing method according to the present inventive concept, the first laser source unit and the first laser head unit, and the second laser source unit and the second laser head unit may be connected to each other, and thus, each laser (for example, the first laser and the second laser) may be effectively provided (or transmitted) to the first laser head unit and the second laser head unit, respectively, and the target object may be scanned by moving the first laser head unit and the second laser head unit. Accordingly, since the first laser head unit and the second laser head unit only need to move within the surface area of the processing area requiring the annealing on the target object, the space (foot-print) occupied by the equipment may be minimized.

In the process (S250) of the scanning the target object, the target object may be scanned by dividing into a plurality f areas and moving the second laser head unit under different scan conditions for each area. Here, the plurality of areas may have different scan conditions and may include a first area and a second area having different scan conditions.

For example, the target object may be divided into the plurality of areas, and also, the first area may be a pre-heating area for preheating the target object, and the second area may be a normal area on which normal scanning is performed. In the case of activating the target object through the scanning of the second laser head unit, a temperature of the target object supported by the stage before the irradiation of the second laser (e.g., for example, 400° C.) requires predetermined energy to rise to an activation temperature (e.g., 1,200° C.). For the predetermined energy (or predetermined accumulated energy), the irradiation of the second laser to the target object may start, and thus, a predetermined time may be required. When the target object is scanned with the laser, heat from the portion immediately irradiated with the laser may be transferred (or diffused) along the scan line. After the predetermined time, the portion (or region) that is irradiated with the second laser and scanned while the heat of the portion raised to the activation temperature is transferred along the scan line by being irradiated with the second laser may be continuously activated by being raised up to the activation temperature. Here, the predetermined time means a time other than 0 second, i.e., may be several seconds (s), several milliseconds (ms), several microseconds (μs), several nanoseconds (ns), several picoseconds (ps), several femtoseconds (fs), several attoseconds (as), zeptoseconds (zs), several yoctoseconds (ys), and the like, and it is sufficient if it is greater than 0 second. In this case, as the energy of the second laser increases, the predetermined energy may reach faster, and the predetermined time may be shortened.

When general scanning is performed as in the general area from a time point at which the second laser is irradiated to the target object, the temperature of the target object may not be raised up to the activation temperature on an area (or portion) on which the scan is performed before the predetermined time reaches the activation temperature, and thus, the activation may not be performed. For this reason, the activation is performed only on the area scanned from the predetermined time (e.g., from about 14 mm after the irradiation start point of the second laser). In this case, it is impossible to use (or utilize) the portion at which the target object is not activated.

Therefore, after starting the irradiation of the second laser to the first area as a preheating area and scanning for more than the predetermined time (sufficient), the second area may be scanned through the general scanning from the time point when the predetermined time has elapsed (or the time point longer than the predetermined time). Thus, the entire target object may be activated, and the entire activated target object may be utilized (or used).

Here, the scan conditions may be a scan speed, the number of times of scanning, a spaced width between the scan lines parallel to each other (or an overlapping width of a laser beam between the scan lines parallel to each other), and an amount of energy accumulated by the second laser per unit area. For example, the first area may be scanned for a period of time longer than the predetermined time by scanning the first area at a scan speed that is slower than that of the second area or by increasing in number of times of scanning on the first area rather than that of the second area. As a result, the amount of energy accumulated by the second laser per unit area on the first area may be greater than that of the second area. Here, the spaced width between scan lines parallel to each other on the first area may be set to be less than that on the second area, or the overlapping width of the (laser) beam (or the second laser beam) between the scan lines parallel to each other may be set to be greater than that on the second area so that the amount of energy accumulated by the second laser per unit area on the first area is greater than that on the second area.

In addition, a surface area of the first area may be set to be less than that of the second area, and it is preferable that a width of the first area in a direction crossing the extension direction of the scan line is the same a width (i.e., a width in a direction crossing the extension direction of the scan line) of the beam of the second laser 12. Since the first area needs to be scanned for a long time, as the surface area of the first area increases, the overall process time for activating the entire target object increases. Thus, the width of the first area in the direction crossing the extension direction of the scan line may be set to be equal to the width of the beam of the second laser so that the first area is reciprocally scanned using the beam of the second laser only for the predetermined time period, and then, the second area is scanned immediately after the predetermined time period. In this case, since the energy by the second laser is accumulated in almost the same area until the predetermined time, the activation of the entire area of the target object may be ensured without the portion of the first area, which is not activated.

As described above, in the present inventive concept, the driving of the first laser head unit that irradiates the first laser and the second laser head unit that irradiates the second laser having the wavelength longer than that of the first laser may be controlled and thus applied to the non-melting process as well as the melting process. In addition, since the wavelength of the first laser is variable, the annealing may be performed on the target object having various thicknesses, and the annealing depth may be adjusted. Here, one or more of the first wavelength laser light source generating the first wavelength laser, the second wavelength laser light source generating the second wavelength laser, and the third wavelength laser light source generating the third wavelength laser may be selectively driven to vary in wavelength of the first laser, and thus, the wavelength of the first laser may vary not only to the single wavelength but also to the mixed wavelength. Therefore, not only the annealing depth may be adjusted, but also, the absorption of the laser may be promoted, and when using the mixed wavelength, the annealing process may be performed even with the relatively low output compared to the case in which the single wavelength is used. In addition, the lasers may be transmitted to the first laser head unit and the second laser head unit through the first optical fiber cable and the second optical fiber cable to allow the first laser head unit and the second laser head unit to move, thereby scanning the target object. Accordingly, since the first laser head unit and the second laser head unit only need to move within the surface area of the processing area requiring the annealing on the target object, the space (foot-print) occupied by the equipment may be minimized. The laser irradiation angle of the first laser head unit and the laser irradiation angle of the second laser head unit may be differently adjusted through the irradiation angle adjusting unit. In this manner, the problem such as the damage of the optical system, which may occur when the laser reflected from the surface of the target object is incident into the laser head unit that is different from the emitting laser head unit, may be prevented.

The term “˜on” used in the above description includes direct contact and indirect contact at a position that is opposite to an upper and lower portion. It is also possible to locate not only the entire top surface or the entire bottom surface but also the partial top surface or the bottom surface, and it is used in the mean that it is opposed in position or contact directly to upper or bottom surface.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

1. A laser annealing apparatus comprising:
a stage configured to support a target object;
a first laser head unit connected to a first laser source unit to irradiate a first laser to the target object;
a second laser head unit connected to a second laser source unit to irradiate a second laser having a wavelength longer than that of the first laser to the target object; and
a control unit configured to control driving of the first laser head unit and the second laser head unit,
wherein the wavelength of the first laser is variable by the control unit.

2. The laser annealing apparatus of claim 1, wherein the first laser source unit comprises:
a first wavelength laser light source configured to generate a first wavelength laser having a blue wavelength band;
a second wavelength laser light source configured to generate a second wavelength laser having a green wavelength band; and
a third wavelength laser light source configured to generate a third wavelength laser having a red wavelength band.

3. The laser annealing apparatus of claim 2, wherein the control unit selectively drives one or more of the first wavelength laser light source, the second wavelength laser light source, and the third wavelength laser light source to allow the wavelength of the first laser to vary.

4. The laser annealing apparatus of claim 1, further comprising:
a head moving unit configured to move the first laser head unit and the second laser head unit;
a first optical fiber cable provided between the first laser source unit and the first laser head unit; and
a second optical fiber cable provided between the second laser source unit and the second laser head unit.

5. The laser annealing apparatus of claim 1, wherein the control unit controls in a selective driving of any one of the first laser head unit and the second laser head unit or a simultaneous driving of the first laser head unit and the second laser head unit.

6. The laser annealing apparatus of claim 5, wherein a beam size of the first laser is equal to or greater than that of the second laser in the simultaneous driving of the first laser head unit and the second laser head unit.

7. The laser annealing apparatus of claim 5, wherein the control unit controls scanning of the first laser head unit and the second laser head unit in the simultaneous driving of the first laser head unit and the second laser head unit so that the first laser and the second laser overlap each other, or the first laser is disposed in front of the second laser in a scan direction.

8. The laser annealing apparatus of claim 1, further comprising an irradiation angle adjusting unit configured to adjust each of a laser irradiation angle of the first laser head unit and a laser irradiation angle of the second laser head unit.

9. The laser annealing apparatus of claim 1, wherein the control unit controls scanning of the second laser head unit under different scan conditions for each area by dividing the target object into a plurality of areas.

10. A laser annealing method comprising:
selecting at least one laser head unit of a first laser head unit that irradiates a first laser having a variable wavelength and a second laser head unit that irradiates a second laser having a wavelength greater than that of the first laser; and
irradiating a laser corresponding to each laser head unit of the first laser and the second laser to a target object from the laser head unit selected from the first laser head unit and the second laser head unit.

11. The laser annealing method of claim 10, further comprising varying the wavelength of the first laser, by selectively driving one or more of a first wavelength laser light source that generates a first wavelength laser having a blue wavelength band, a second wavelength laser light source that generates a second wavelength laser having a green wavelength band and a third wavelength laser light source that generates a third wavelength laser having a red wavelength band.

12. The laser annealing method of claim 11, further comprising setting driving of the first laser head unit and the second laser head unit in selective driving or simultaneous driving,
wherein, in the selecting at least one laser head unit, the at least one laser head unit is selected from the first laser head unit and the second laser head unit according to the set driving of the first laser head unit and the second laser head unit.

13. The laser annealing method of claim 12, wherein, in the setting of the selective driving or the simultaneous driving, when activating at least a portion of the target object, the simultaneous driving is set.

14. The laser annealing method of claim 13, further comprising:
generating free carriers by the first laser; and
absorbing the second laser to activate impurities in the target object.

15. The laser annealing method of claim 13, further comprising adjusting each of a laser irradiation angle of the first laser head unit and a laser irradiation angle of the second laser head unit.

16. The laser annealing method of claim 12, wherein, in the setting of the selective driving or the simultaneous driving, when activating at least a portion of the target object, the selective driving of the first laser head unit is set.

17. (canceled)

18. The laser annealing method of claim 12, wherein, in the setting of the selective driving or the simultaneous driving, when at least partially crystallizing the target object, the selective driving of the first laser head unit is set.

19. The laser annealing method of claim 18, wherein, in the varying the wavelength of the first laser, the wavelength of the first laser varies according to a target depth for a crystallization.

20. The laser annealing method of claim 10, further comprising scanning the target object by moving the selected laser head unit,
wherein the first laser head unit and the second laser head unit are connected to a first laser source unit for generating the first laser and a second laser source unit for generating the second laser by optical fiber cables, respectively.

21. The laser annealing method of claim 20, wherein, in the scanning the target object, the target object is scanned while moving the second laser head unit under different scan conditions for each area by dividing the target object into a plurality of areas.
